(19) United States
(12) Patent Application Publication
(10) Pub. No.: US 2010/0306622 A1
(43) Pub. Date: Dec. 2, 2010

(54) MEMORY SYSTEM AND DATA TRANSFER METHOD

(76) Inventor: Takahide NISHIYAMA, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/649,724

(22) Filed: Dec. 30, 2009

(30) Foreign Application Priority Data
May 28, 2009 (JP) 2009-129261

(51) Int. Cl. G06F 11/00; G06F 12/00; G11C 29/00

(52) U.S. Cl. 714/763; 711/103; 714/5; 714/E11.03

(57) ABSTRACT

A memory system includes a nonvolatile memory configured to store data, a first buffer configured to temporarily store data from the nonvolatile memory, a correction circuit configured to correct an error of data from the first buffer, a second buffer configured to temporarily store data from the correction circuit, a bus configured to receive data from the second buffer, a command sequence unit configured to issue a command for data transfer between modules, the modules including the first buffer, the correction circuit and the second buffer, and a command decode unit configured to decode the command and to generate a control signal for controlling the data transfer.

### CROSS-REFERENCE TO RELATED APPLICATIONS

This application is based upon and claims the benefit of priority from prior Japanese Patent Application No. 2009-129261, filed May 28, 2009, the entire contents of which are incorporated herein by reference.

### BACKGROUND OF THE INVENTION

1. Field of the Invention

The present invention relates to a memory system and a data transfer method, and relates to, for example, a memory system including a sequencer which controls data transfer.

2. Description of the Related Art

As a nonvolatile semiconductor memory, there is known a NAND flash memory which is a kind of electrically erasable programmable read-only memory (EEPROM) which electrically executes data write and data erase.

In a memory system including the NAND flash memory, a plurality of modules are connected to one (or plural) system bus, and switching of data transfer between the modules is executed, with intervention of a firmware (FW) process by a central processing unit (CPU). Thus, each time a single data transfer operation between modules is completed, an interrupt for notifying the completion of the transfer operation is generated. The next transfer operation is executable after the setting for the next operation is performed by the FW process.

Hence, if an error correction circuit, which error-corrects data that is read from the NAND flash memory, and a plurality of memory buffers are present, the number of processes for switching data transfer between modules increases. Consequently, a great number of interrupts occur each time transfer between modules is completed. In other words, the time in which the FW process intervenes becomes very long. This considerably deteriorates the latency of data transfer.

A patent document (Jpn. Pat. Appln. KOKAI Publication No. 2003-141888) discloses a semiconductor memory device for storage, which can be directly connected to a CPU bus or a general-purpose bus.

### BRIEF SUMMARY OF THE INVENTION

According to an aspect of the present invention, there is provided a memory system comprising:

a nonvolatile memory configured to store data;

a first buffer configured to temporarily store data from the nonvolatile memory;

a correction circuit configured to correct an error of data from the first buffer;

a second buffer configured to temporarily store data from the correction circuit;

a bus configured to receive data from the second buffer;

a command sequence unit configured to issue a command for data transfer between modules, the modules including the first buffer, the correction circuit and the second buffer; and

a command decode unit configured to decode the command and to generate a control signal for controlling the data transfer.

According to an aspect of the present invention, there is provided a data transfer method of a memory system, the memory system comprising:

a nonvolatile memory configured to store data;

a first buffer configured to temporarily store data from the nonvolatile memory;

a correction circuit configured to correct an error of data from the first buffer;

a second buffer configured to temporarily store data from the correction circuit; and

a bus configured to receive data from the second buffer,

the method comprising:

issuing a command for data transfer between modules, the modules including the first buffer, the correction circuit and the second buffer; and

decoding the command and generating a control signal for controlling the data transfer.

### BRIEF DESCRIPTION OF THE SEVERAL VIEWS OF THE DRAWING

FIG. 1 is a block diagram showing the structure of a memory system 1 according to a first embodiment of the present invention;

FIG. 2 is a block diagram showing the structure of a command sequence unit 14;

FIG. 3 is a block diagram showing the structure of a command decode unit 15;

FIG. 4 is a schematic view illustrating the relationship between command sequencers SEQ and data transfer between modules;

FIG. 5 is a flow chart illustrating the operation of a command sequencer SEQ4;

FIG. 6 is a schematic view illustrating the state of data in a memory buffer 17, an error correction circuit 19 and a memory buffer 20;

FIG. 7 is a flow chart illustrating the operation of a command sequencer SEQ5;

FIG. 8 is a flow chart illustrating the operation of a command sequencer SEQ1;

FIG. 9 is a block diagram showing the structure of a memory system 1 according to a second embodiment of the present invention; and

FIG. 10 is a schematic view showing the structure of a command sequencer group according to a third embodiment of the invention.

### DETAILED DESCRIPTION OF THE INVENTION

The embodiments of the present invention will be described hereinafter with reference to the accompanying drawings. In the description which follows, the same or functionally equivalent elements are denoted by the same reference numerals, to thereby simplify the description.

### First Embodiment

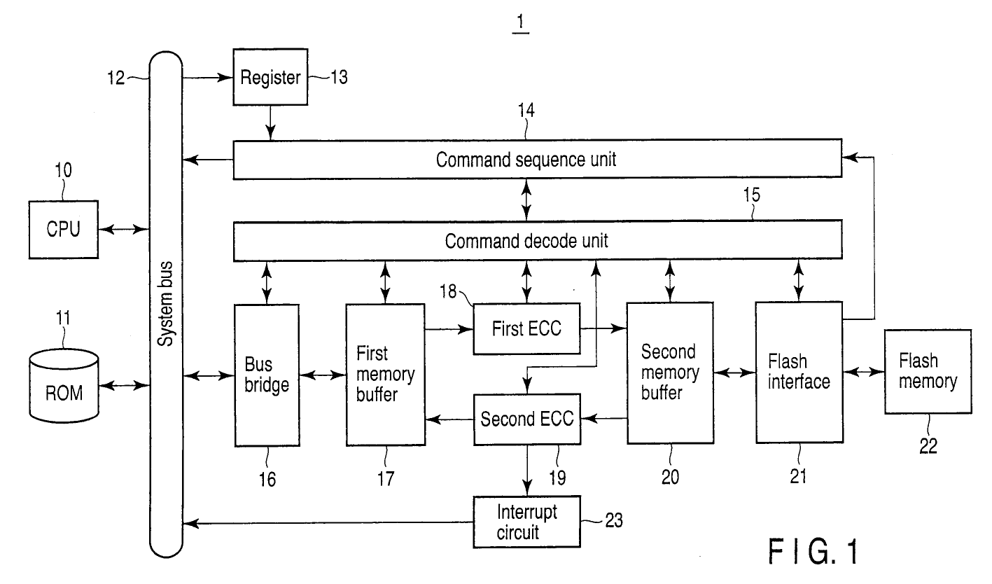

FIG. 1 is a block diagram showing the structure of a memory system 1 according to a first embodiment of the present invention. The memory system 1 comprises a central processing unit (CPU) 10, a read-only memory (ROM) 11, a system bus 12, a register 13, a command sequence unit 14, a command decode unit 15, a bus bridge 16, a first memory buffer 17, a first error correction (error checking and correcting (ECC)) circuit 18, a second error correction (ECC) circuit 19, a second memory buffer 20, a flash interface 21, a flash memory 22 which is a nonvolatile memory, and an interrupt circuit 23.

The CPU 10 executes an overall control of the operation of the memory system 1 by using firmware (FW) which is stored in the ROM 11. The CPU 10 is connected to the system bus 12, and executes data transfer to/from the respective modules via the system bus 12. The “module”, in this context, refers to a functional unit which realizes a desired operation and function, and in this embodiment the module refers to each functional block shown in FIG. 1.

The flash memory 22 is composed of, for instance, a NAND flash memory. The flash memory 22 comprises a plurality of blocks which are units of data erasure. Each of the blocks is configured such that a plurality of flash memory cells are arrayed in a matrix. Each of the blocks includes pages each comprising a plurality of bits. In the flash memory 22, data read and data write are executed in units of the page.

The flash interface 21 executes an interface process with the flash memory 22. Specifically, the flash interface 21 executes data erase, data write and data read for the flash memory 22. For this purpose, the flash interface 21 includes a column decoder which selects a column of the flash memory 22, a row decoder which selects a row of the flash memory 22, a sense amplifier for reading data from the memory cell, and a data cache for holding read data and write data.

The command sequence unit 14 issues a command for instructing data transfer between modules. In addition, the command sequence unit 14 issues a command in accordance with an operation mode which is set in the register 13. The setting of the operation mode in the register 13 is executed by the CPU 10.

The command decode unit 15 decodes a command which is sent from the command sequence unit 14, and generates, in accordance with this command, a control signal for controlling data transfer between modules.

The first ECC circuit 18 receives write data, and generates a parity code for the write data. In addition, the first ECC circuit 18 generates a parity code by using a frame of a predetermined data size as a unit of calculation. The party code is added to the write data and is transferred together with the write data. The second ECC circuit 19 receives read data, and corrects an error of read data by using a parity code which is added to the read data.

The memory buffer 17 temporarily stores write data which is in a state immediately before a parity code is added thereto, or read data which has been error-corrected by the ECC circuit 19. The memory buffer 20 temporarily stores read data from the flash memory 22, or write data which is immediately due to be written in the flash memory 22 and to which a parity code has been added by the ECC circuit 18. Each of the memory buffers 17 and 20 is composed of, for instance, a random access memory (RAM). The bus bridge 16 executes an interface process between the memory buffer 17 and the system bus 12.

The interrupt circuit 23 generates an interrupt to the CPU 10, and notifies the CPU 10 of abnormal termination of data transfer in this interrupt. Specifically, in the case where the ECC circuit 19 determines the disability of error correction, the interrupt circuit 23 reports this fact and the frame number which is associated with the disability of error correction.

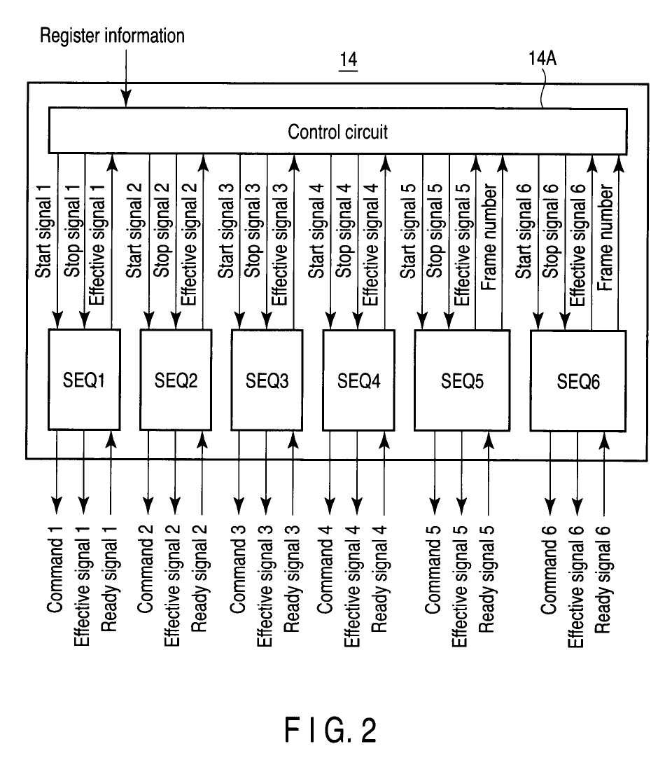

FIG. 2 is a block diagram showing the structure of the command sequence unit 14. The command sequence unit 14 comprises a command sequencer group, which is composed of a plurality of command sequencers SEQ, and a control circuit 14A which executes an overall control of the command sequencer group. FIG. 2 shows, by way of example, six command sequencers SEQ1 to SEQ6.

The command sequencer group comprises that number of command sequencers SEQ, which corresponds to data transfers between modules. The command sequencer group is configured to issue a specific command sequence for controlling the transfer between modules, on the basis of the operation mode which is set in the register 13. This command sequence is generated independently in association with each data transfer between modules. The respective modules execute, in parallel, operations corresponding to command sequences.

The command sequencer SEQ1 issues a command sequence which is necessary for a data transfer process between the associated modules. Specifically, each time the command sequencer SEQ1 receives a ready signal 1 from the command decode unit 15, the command sequencer SEQ1 successively sends a command 1 to the command decode unit 15. The ready signal indicates that a series of operations corresponding to the command has been completed, and the ready signal is activated when the series of operations has been completed. In addition, the command sequencer SEQ1 generates, together with the generated command 1, an effective signal 1 indicating whether the command 1 is effective or not. The effective signal 1 is sent to the command decode unit 15 and the control circuit 14A. The other command sequencers SEQ2 to SEQ6 have the same basic structure as the command sequencer SEQ1.

The control circuit 14A determines which of the command sequencers SEQ is to be operated, on the basis of resister information (operation mode) which is sent from the register 13. For this control, the control circuit 14A generates a start signal for starting the operation of the command sequencer SEQ, and a stop signal for stopping the operation of the command sequencer SEQ, and sends the start signal and the stop signal to the command sequencer SEQ. In addition, the control circuit 14A determines the timing of sending the start signal and stop signal, on the basis of the effective signal which is received from each command sequencer SEQ, and frame numbers (to be described later) which are received from some of the command sequencers, for instance, the command sequencers SEQ5 and SEQ6.

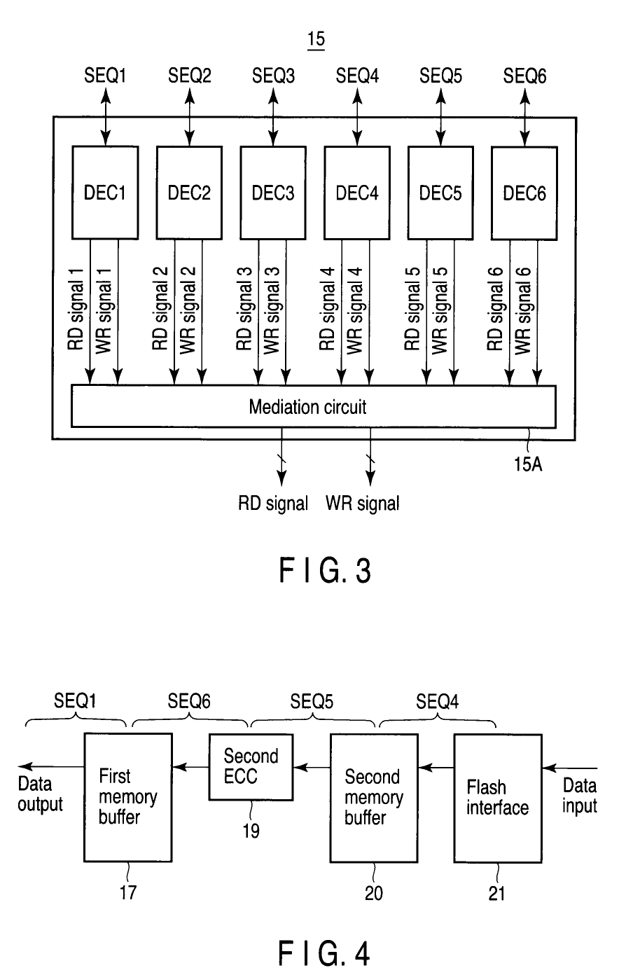

FIG. 3 is a block diagram showing the structure of the command decode unit 15. The command decode unit 15 comprises a command decode group which is composed of a plurality of command decoders DEC corresponding to the plural command sequencers SEQ, and a mediation circuit (arbiter circuit) 15A which mediates control signals that are generated by the command decoder group. FIG. 3 shows, by way of example, six command decoders DEC1 to DEC6 corresponding to the six command sequencers SEQ1 to SEQ6.

The command decoder DEC1 receives the command 1 and effective signal 1 from the command sequencer SEQ1, and interprets the command 1. If the effective signal 1 is in the active state, the command decoder DEC1 executes, according to the command 1, the write control and read control between the associated modules. Specifically, if the command 1 is issued from the command sequencer SEQ1, the command decoder DEC1 generates an address signal and a read signal (both signals are referred to as “RD signal 1” as a whole) for reading out data from the address corresponding to the command 1, and sends the RD signal 1 to the module of the data sending side (source side). In addition, the command decoder DEC1 generates an address signal and a write signal (both signals are referred to as “WR signal 1” as a whole) for writing read data in a destination (destination-side) module, and sends the WR signal 1 to the destination-side module.

Further, the command decoder DEC1 executes flag control for the modules. Each module has a region for storing a flag. By this flag, the state of the module can be confirmed. Specifically, if data transfer is completed, the command decoder DEC1 clears the flag of the source-side module (“data free state”) and sets the flag in the destination-side module (“data holding state”). A control signal necessary for the flag control is also included in the RD signal 1 and WR signal 1. When this series of operations is completed, the command decoder DEC1 returns a ready signal to the command sequencer SEQ1. The other command decoders DEC2 to DEC6 have the same basic structure as the command decoder DEC1.

The mediation circuit 15A receives the RD signals and WR signals from the respective command decoders DEC, and mediates these RD signals and WR signals. The mediation circuit 15A sends the RD signal and WR signal to the modules for which the corresponding data transfer process is executed. By the operation of the mediation circuit 15A, the read operation is executed in the source-side module and the write operation is executed in the destination-side module.

### (Operation)

Next, the operation of the memory system 1 having the above-mentioned structure is described. A description is given of, by way of example, the operation in a process from the read data from the flash memory 22 to the transfer of the read data to the system bus 12. To start with, the CPU 10 sets an operation mode in the register 13. Thereby, the command sequence unit 14 starts this operation mode.

FIG. 4 is a schematic view illustrating the relationship between the command sequencers SEQ and the data transfer between modules. The command sequencers, which operate at the time of read, are SEQ1, SEQ4, SEQ5 and SEQ6. The order of operations of the command sequencers in the direction of data flow is expressed by “SEQ4→SEQ5→SEQ6→SEQ1”. Although a description is omitted, the SEQ2 and SEQ3 are command sequencers which operate at the time of data write.

The command sequencer SEQ4 issues a command sequence with respect to the data transfer between the flash memory 21 and the memory buffer 20. The command sequencer SEQ5 issues a command sequence with respect to the data transfer between the memory buffer 20 and the ECC circuit 19. The command sequencer SEQ6 issues a command sequence with respect to the data transfer between the ECC circuit 19 and the memory buffer 17. The command sequencer SEQ1 issues a command sequence with respect to the data transfer between the memory buffer 17 and the system bus 12. The command decoders DEC1, DEC4, DEC5 and DEC6 decode the commands from the command sequencers, and make the transition to a data transfer process.

The read process of data from the flash memory 22 is executed by the flash interface 21. The command sequencers have no relation to this process.

In the present embodiment, the frame, which is a unit for calculating a parity code, extends over, e.g. three pages. As has been described above, one page is a read/write unit of the flash memory 22, and is, e.g. 8 Kbytes. Immediately after the start of data read, since data is not complete, the operation state is a data wait state. To begin with, in order to read data for three pages, the command sequencer SEQ4 issues commands three times separately, and transfers the data from the flash interface 21 to the memory buffer 20.

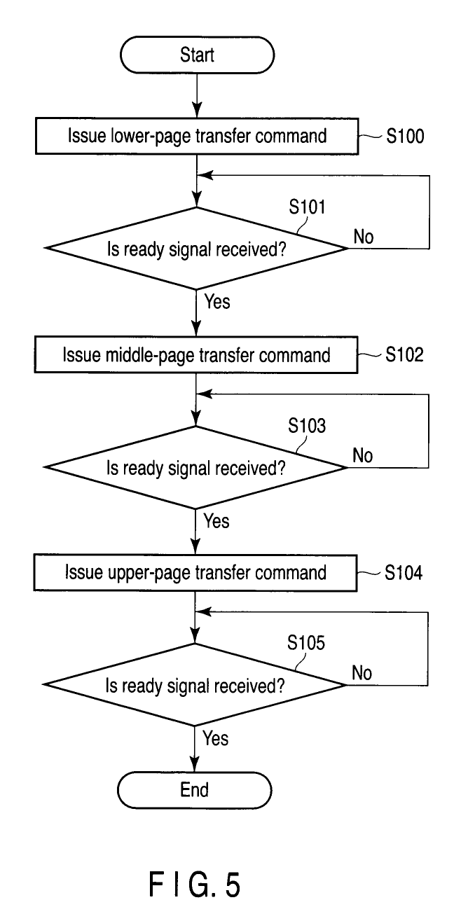

FIG. 5 is a flow chart illustrating the operation of the command sequencer SEQ4. It is assumed that the three pages comprise a lower page, a middle page and an upper page. The command sequencer SEQ4 issues a lower-page transfer command (step S100). If the command sequencer SEQ4 receives a ready signal 4 from the command decoder DEC4 in response to the lower-page transfer command (step S101), the command sequencer SEQ4 issues a middle-page transfer command (step S102). If the command sequencer SEQ4 receives a ready signal 4 from the command decoder DEC4 in response to the middle-page transfer command (step S103), the command sequencer SEQ4 issues an upper-page transfer command (step S104). If the command sequencer SEQ4 receives a ready signal 4 from the command decoder DEC4 in response to the upper-page transfer command (step S105), the data transfer process of the command sequencer SEQ4 is completed.

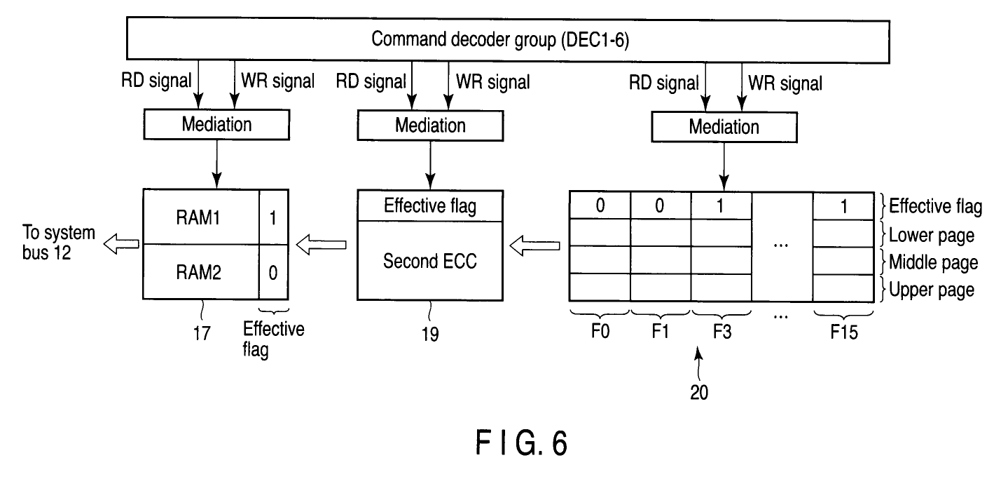

FIG. 6 is a schematic view illustrating the state of data in the memory buffer 17, the ECC circuit 19 and the memory buffer 20. If the command decoder DEC4 receives the lower-page transfer command from the command sequencer SEQ4, the command decoder DEC4 generates a WR signal corresponding to the lower-page transfer command. The WR signal from the command decoder DEC4 is mediated by the mediation circuit 15A, and then the WR signal is sent to the memory buffer 20. By the above-described series of operations of the command sequencer SEQ4, the data for the three pages (lower page, middle page and upper page) is stored in the memory buffer 20. Specifically, the memory capacity of the memory buffer 20 is 24 Kbytes. In FIG. 6, the three pages are horizontally disposed in three rows in the memory buffer 20. If predetermined data is stored in the memory buffer 20, an effective flag indicating that the data has become complete is set by the command decoder DEC4, and data transfer from the memory buffer 20 to the ECC circuit 19 is enabled.

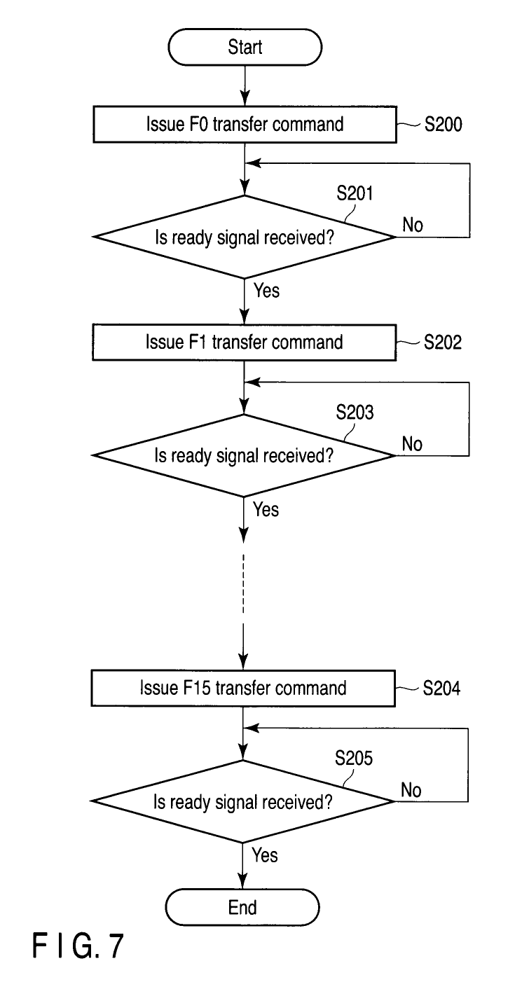

Subsequently, the command sequencer SEQ5 issues commands in association with each frame, and transfers data from the memory buffer 20 to the ECC circuit 19. FIG. 7 is a flow chart illustrating the operation of the command sequencer SEQ5.

In the data transfer from the memory buffer 20 to the ECC circuit 19, the transfer amount of data at this time is equal to the process size of the ECC circuit, and the issuance of a command is executed in units of this size. The reason why the data transfer amount of one command is defined by the process unit (expressed as “1 frame”) of the ECC circuit is that this is optimal when transition occurs to a resume process from a halt, such as an interruption, due to the disability of correction occurring during the process. 1 frame is, e.g. 1.5 Kbytes. Accordingly, the data for three pages is transferred in portions corresponding to 16 frames (F0 to F15), respectively. The frame number, which is output from the sequencer (e.g. SEQ5, SEQ6 in FIG. 2) to the control circuit 14A, corresponds to the number i of a frame Fi (i=0 to 15).

The command sequencer SEQ5 issues a frame F0 transfer command (step S200). If the command sequencer SEQ5 receives a ready signal 5 from the command decoder DEC5 in response to the frame F0 transfer command (step S201), the command sequencer SEQ5 issues a frame F1 transfer command (step S202). The same process is repeated for 16 frames (F0 to F15). If the command sequencer SEQ5 receives a ready signal 5 corresponding to the frame F15 (step S205), the data transfer process of the command sequencer SEQ5 is completed.

In FIG. 6, if the command decoder DEC5 (see FIG. 3) in the command decode unit 15 receives the frame F0 transfer command from the command sequencer SEQ5, the command decoder DEC5 generates the corresponding RD signal and WR signal. The RD signal and WR signal are mediated by the mediation circuit 15A, and then sent to the memory buffer 20 and ECC circuit 19. Subsequently, the command decoder DEC5 clears the effective flag of the frame F0.

The ECC circuit 19 receives the frame F0 from the memory buffer 20. The ECC circuit 19 error-corrects the frame F0 by using the parity code which is included in the frame F0. At this time, if error correction is disabled, the ECC circuit 19 sends to the interrupt circuit 23 a signal indicating the disability of error correction. Upon receiving this signal, the interrupt circuit 23 generates an interrupt to the CPU 10, and notifies the CPU 10 of the disability of error correction. Further, in this interrupt, the interrupt circuit 23 reports the frame number of the frame, with respect to which the error correction is disabled.

In the case where there is no error in the frame F0 or the error correction for the frame F0 has normally been executed by the ECC circuit 19, that is, in the case where no interrupt occurs due to the disability of error correction, the command decoder DEC5 sets in the ECC circuit 19 the effective flag indicating that the preparation for the data is completed.

Similarly, the data transfer and error correction are executed for the frames F1 to F15. At this stage, since the data for the 16 frames is already stored in the memory buffer 20, the data transfer for the 16 frames can successively be executed unless an interrupt due to the disability of error correction occurs during this process.

Next, the operation of the command sequencer SEQ6 is described. In parallel with the data transfer by the command sequencer SEQ5, the command sequencer SEQ6 issues commands in association with each frame, and the data is transferred from the ECC circuit 19 to the memory buffer 17. The operation of the command sequencer SEQ6 is the same as the operation of the command sequencer SEQ5 shown in FIG. 7, except that the source and destination designated by the commands are varied.

In FIG. 6, if the command decoder DEC6 receives the frame F0 transfer command from the command sequencer SEQ6, the command decoder DEC6 generates the corresponding RD signal and WR signal. The RD signal and WR signal are mediated by the mediation circuit 15A, and then sent to the ECC circuit 19 and the memory buffer 17. Thereby, the frame F0 is transferred to a RAM1 of the memory buffer 17. Subsequently, the command decoder DEC6 clears the effective flag in the ECC circuit 19. In addition, if the data for one frame is transferred to the RAM1, the command decoder DEC 6 sets the effective flag of the RAM1.

Subsequently, like the frame F0, the frame F1 is error-corrected. The command decoder DEC6 transfers the frame F1 to a RAM2 of the memory buffer 17. The memory buffer 17 comprises, for example, two RAMs, i.e. RAM1 and RAM2. Each of the RAM1 and RAM2 stores data for one frame. Specifically, the capacity of each of the RAM1 and RAM2 is 1.5 Kbytes. If the data for one frame is transferred to the RAM2, the command decoder DEC6 sets the effective flag of the RAM2.

Like the frames F0 and F1, the error correction and data transfer are executed for the frames F2 and F3. The frames F2 and F3 are transferred to the RAM1 and RAM2, respectively. Similarly, the error correction is executed for the frames F4 to F15, and the data is transferred alternately to the RAM1 and RAM2.

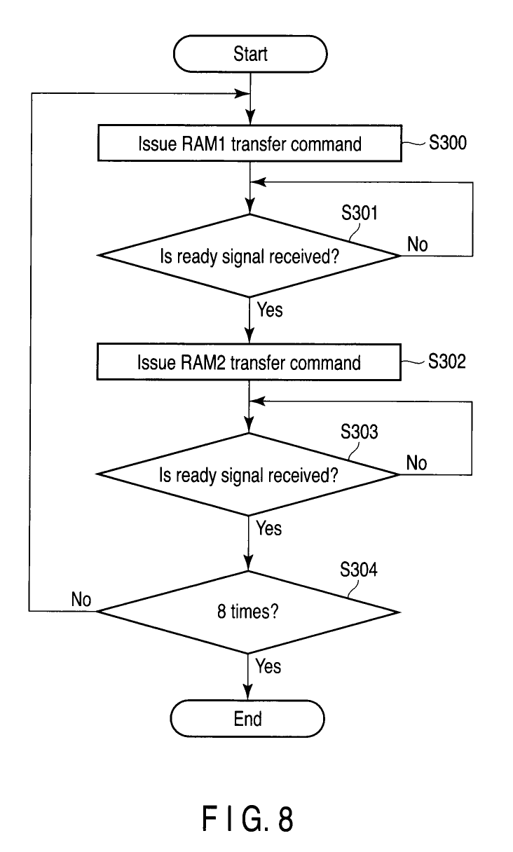

Next, the operation of the command sequencer SEQ1 is described. In parallel with the data transfer by the command sequencer SEQ6, the command sequencer SEQ1 issues commands in association with each RAM, and the data is transferred from the memory buffer 17 to the system bus 12. FIG. 8 is a flow chart illustrating the operation of the command sequencer SEQ1.

The command sequencer SEQ1 issues a RAM1 transfer command (step S300). If the command sequencer SEQ1 receives a ready signal 1 from the command decoder DEC1 in response to the RAM1 transfer command (step S301), the command sequencer SEQ1 issues a RAM2 transfer command (step S302). Then, the command sequencer SEQ1 receives a ready signal 1 from the command decoder DEC1 (step S303). At this time point, the data for two frames has been transferred to the system bus 12.

The process of steps S300 to 5303 is repeated eight times (step S304). Thereby, the data for 16 frames (F0 to F15) can be transferred from the memory buffer 17 to the system bus 12.

In FIG. 6, if the command decoder DEC1 receives the RAM1 transfer command from the command sequencer SEQ1, the command decoder DEC1 generates the corresponding RD signal. The RD signal is mediated by the mediation circuit 15A, and then sent to the memory buffer 17. Thereby, one frame stored in the RAM1 of the memory buffer 17 is transferred to the system bus 12. Subsequently, the command decoder DEC1 clears the effective flag of the RAM1. The transfer operation of the RAM2 of the memory buffer 17 is the same as that of the RAM1. By repeating the transfer operation, the data for 16 frames (F0 to F15) is transferred from the memory buffer 17 to the system bus 12.

At last, if all data transfer is normally finished, the flash interface 21 reports this to the command sequence unit 14. Upon receiving the report, the control circuit 14A generates an interrupt to the CPU 10, and informs the CPU of the normal end of the data transfer.

As has been described above in detail, in the first embodiment, the command sequence unit 14 and command decode unit 15 are newly provided, aside from the CPU 10. The command sequence unit 14 and command decode unit 15 are configured to execute the data transfer control from the flash memory 22 to the system bus 12 via the ECC circuit, or to execute the data transfer control in the reverse data path. The command sequence unit 14 includes the command sequencer group comprising that number of command sequencers, which corresponds to the data transfer between modules, and each command sequencer issues a command sequence for instructing the associated data transfer. The command decode unit 15 comprises that number of command decoders, which corresponds to the number of command sequencers, and each command decoder generates, in response to the command from the command sequencer, the control signal for controlling the data write and read between the associated modules.

Thus, according to the first embodiment, during the time period from the start of the system, the data can successively be transferred from the flash memory 22 to the system bus 12, without intervention of a FW process by the CPU 10, unless an interrupt due to the disability of error correction is generated by the error correction circuit 19. Thereby, the processing load on the CPU 10 can be reduced, and the degradation in latency in the conventional FW process can remarkably be improved.

In the case where the ECC circuit 19 determines the disability of error correction, the interrupt circuit 23 generates an interrupt and informs the CPU 10 of the abnormal end of data transfer and the frame number of the frame which cannot be error-corrected. Thereby, the CPU 10 can immediately recognize the abnormal end, and can properly perform a subsequent FW process.

The unit of data transfer is set to be equal to the frame that is a process unit of the ECC circuit. Thereby, even in the case where the data transfer process is temporarily interrupted due to the abnormal end, the transfer process can be resumed from the frame next to the frame which cannot be error-corrected. As a result, the ECC process and data transfer process, which have been executed prior to the abnormal end, can be prevented from becoming useless, and the efficiency of data transfer can be improved.

Moreover, the state management of each module is executed by using the effective flag. Thereby, since it is possible to easily determine whether a certain module is a source-side module or a destination-side module, the data transfer process can exactly be executed.

In the first embodiment, the description is directed to the case of transferring the data for 16 frames. Alternatively, data for more than or less than 16 frames can be transferred by varying the content of setting of the command sequence group.

### Second Embodiment

As described in connection with the first embodiment, the data that is read from the flash memory 22 is stored in the memory buffer 20, and the ECC process for 16 frames is executed by using the ECC circuit 19. In this case, however, the ECC process for 16 frames requires a very long time. Thus, in the case of reading data of 16 frames or more, if the number of memory buffers 20 is one, the read operation of the flash memory 22 is caused to wait for a very long time, leading to considerable degradation in latency. Taking this into account, in the second embodiment, there are provided two memory buffers which store data that is read from the flash memory 22. Specifically, the memory buffer 20 is configured to have a bank structure, and thereby the process of data read from the flash memory 22 and the error correction process by the ECC circuit 19 are executed in parallel.

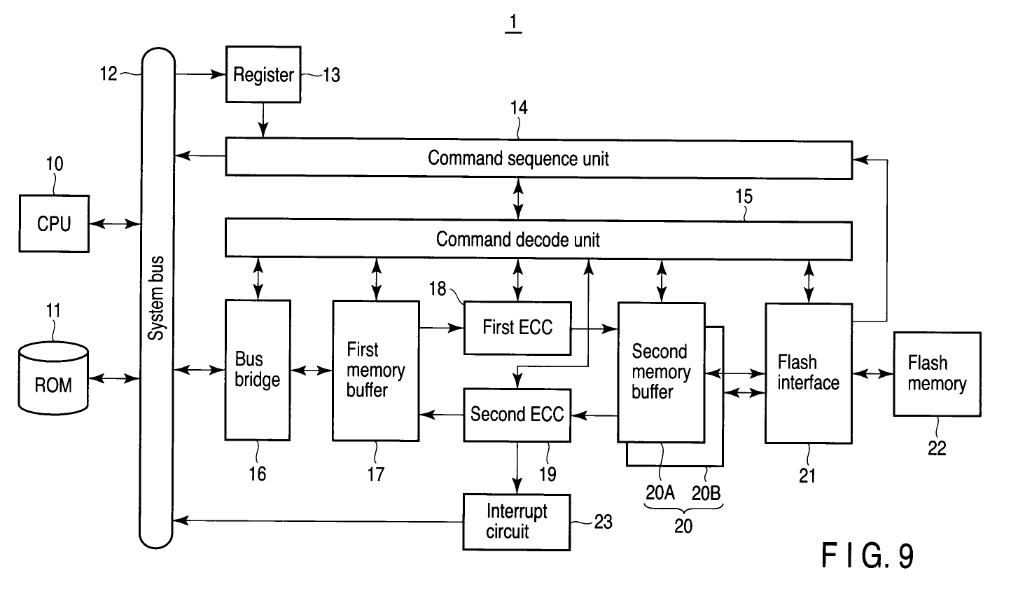

FIG. 9 is a block diagram showing the structure of the memory system 1 according to the second embodiment of the present invention. The memory buffer 20 has a bank structure. Specifically, the memory buffer 20 comprises two memory buffers 20A and 20B. Each of the memory buffers 20A and 20B stores data for three pages. Specifically, each of the memory buffers 20A and 20B has a memory capacity of 24 Kbytes. In the other structural aspects, the second embodiment is the same as the first embodiment.

The command sequencer SEQ4 transfers the data, which is read from the flash memory 22, alternately to the memory buffers 20A and 20B in units of three pages. The destination-side memory buffer is selected by using an effective flag which is provided therein.

In the case of transferring the data from the memory buffer 20 to the ECC circuit 19, the command sequencer SEQ5 uses the memory buffers 20A and 20B by switching them in every 16 frames. In the other respects, the data transfer operation of the second embodiment is the same as that of the first embodiment.

As has been described above in detail, according to the second embodiment, the memory buffer 20 is configured to have the bank structure, so that the read process from the flash memory 22 and the correction process by the ECC circuit 19 may be executed in parallel. Thereby, the latency can be improved.

If the transfer time from the flash memory 22 to the memory buffer is approximately equal to the correction process time by the ECC circuit 19, it should suffice if the number of memory buffers 20 is two. If the ratio between the transfer time and the correction process time is considerably different, for example, if the correction process time is much longer, the degradation in latency can be prevented by increasing the number of memory buffers.

In the second embodiment, the description has been given of the case where the memory system 1 comprises two or more memory buffers 20. This presupposes the use of 1-port memory buffers. However, if a 2-port memory buffer is used, this memory buffer can execute data read and data write at the same time. If such a 2-port memory buffer is used, the number of memory buffers may be one.

### Third Embodiment

In the first embodiment, the command sequencer group issues specific command sequences in accordance with operation modes. Instead, in the third embodiment, a command table system (e.g. instruction RAM) is adopted in the command sequencer group, so that commands may be programmed in the command table.

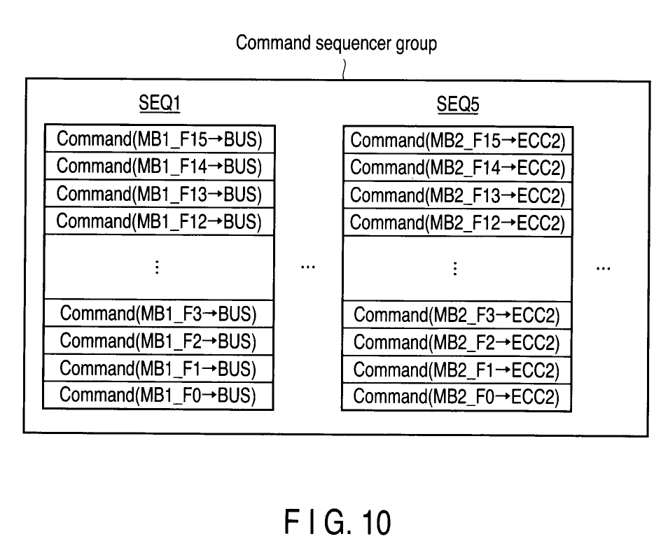

FIG. 10 is a schematic view showing the structure of a command sequencer group according to the third embodiment of the invention. Like the first embodiment, the command sequencer group comprises that number of command sequencers, which corresponds to data transfer between modules.

Each command sequencer SEQ includes a command table. Commands included in the command table are freely rewritable. Specifically, each command sequencer SEQ is composed of a memory such as a RAM. FIG. 10 shows, by way of example, the details of the command sequencers SEQ1 and SEQ5.

In the command sequencer SEQ1 shown in FIG. 10, for example, “command (MB1_F0→BUS)” is a command designating an instruction to transfer the frame F0 from the first memory buffer 17 (MB1) to the system bus 12 (BUS). By sequentially executing the commands in the command table included in the command sequencer SEQ1, 16 frames (F0 to F15) can be transferred from the memory buffer 17 to the system bus 12.

In the command sequencer SEQ5 shown in FIG. 10, for example, “command (MB2_F0→ECC2)” is a command designating an instruction to transfer the frame F0 from the second memory buffer 20 (MB2) to the second ECC circuit 19 (ECC2). By sequentially executing the commands in the command table included in the command sequencer SEQ5, 16 frames (F0 to F15) can be transferred from the memory buffer 20 to the ECC circuit 19.

As has been described in detail, according to the third embodiment, the processing load on the CPU 10 can be reduced, and a part of the commands stored in the command table can be rewritten. Thereby, the order of data transfer can flexibly be changed, and various modes of data transfer and access to the flash memory can adaptively be realized.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A memory system comprising:
a nonvolatile memory configured to store data;
a first buffer configured to temporarily store data from the nonvolatile memory;
a correction circuit configured to correct an error of data from the first buffer;
a second buffer configured to temporarily store data from the correction circuit;
a bus configured to receive data from the second buffer;
a command sequence unit configured to issue a command for data transfer between modules, the modules including the first buffer, the correction circuit and the second buffer; and
a command decode unit configured to decode the command and to generate a control signal for controlling the data transfer.

2. The system according to claim 1, wherein
the command sequence unit comprises a plurality of command sequencers which are provided in association with data transfers between the modules, and
the command decode unit comprises a plurality of command decoders which corresponds to the command sequencers.

3. The system according to claim 1, wherein
the command decode unit activates a ready signal when data transfer corresponding to the command is completed, and
the command sequence unit issues a next command when the ready signal is activated.

4. The system according to claim 1, wherein
each module stores a flag indicating a state of the module, and
the command decode unit controls the module in accordance with the flag.

5. The system according to claim 4, wherein the command decode unit rewrites the flag.

6. The system according to claim 1, further comprising:
a central processing unit (CPU) connected to the bus; and
an interrupt circuit configured to generate an interrupt to the CPU when disability of correction is determined by the correction circuit.

7. The system according to claim 6, wherein the interrupt circuit notifies the CPU of information including a frame number of a frame for which error correction is disabled.

8. The system according to claim 1, wherein
the correction circuit corrects an error in units of a frame having a specified data size, and
the command sequence unit executes data transfer in units of the frame.

9. The system according to claim 8, wherein each of the first buffer and the second buffer stores a plurality of frames.

10. The system according to claim 1, wherein the command sequence unit executes data transfers between the modules in parallel.

11. The system according to claim 1, further comprising a register configured to store an operation mode,
wherein the command sequence unit issues a command corresponding to the operation mode.

12. The system according to claim 1, wherein the first buffer comprises a plurality of buffers which operate in parallel.

13. The system according to claim 1, wherein the command sequence unit includes a memory configured to store a command table.

14. The system according to claim 1, wherein the nonvolatile memory is a flash memory.

15. A data transfer method of a memory system, the memory system comprising:
a nonvolatile memory configured to store data;
a first buffer configured to temporarily store data from the nonvolatile memory;
a correction circuit configured to correct an error of data from the first buffer;
a second buffer configured to temporarily store data from the correction circuit; and
a bus configured to receive data from the second buffer,
the method comprising:
issuing a command for data transfer between modules, the modules including the first buffer, the correction circuit and the second buffer; and
decoding the command and generating a control signal for controlling the data transfer.

16. The method according to claim 15, further comprising:
issuing a plurality of commands in parallel in association with data transfers between the modules; and
decoding the commands in parallel, and generating control signals in parallel for controlling the data transfers.

17. The method according to claim 15, further comprising:
activating a ready signal when data transfer corresponding to the command is completed; and
issuing a next command when the ready signal is activated.

18. The method according to claim 15, further comprising setting in each module a flag indicating a state of the module,
wherein the control signal is generated in accordance with the flag.

19. The method according to claim 15, wherein
the memory system includes a CPU connected to the bus, and
the method further comprises generating an interrupt to the CPU when disability of correction is determined by the correction circuit.

20. The method according to claim 15, wherein
the correction circuit corrects an error in units of a frame having a specified data size, and
the data transfer is executed in units of the frame.
